(19) United States
(12) Patent Application Publication
(10) Pub. No.: US 2025/0056884 A1
(43) Pub. Date: Feb. 13, 2025

(54) ARRAY SUBSTRATE, DISPLAY PANEL AND DISPLAY DEVICE

(71) Applicant: HKC CORPORATION LIMITED, Shenzhen (CN)

(72) Inventors: Rong LI, Shenzhen (CN); Lidan YE, Shenzhen (CN)

(21) Appl. No.: 18/753,181

(22) Filed: Jun. 25, 2024

(30) Foreign Application Priority Data
Aug. 7, 2023 (CN) 202310981834.4

(51) Int. Cl. H01L 27/12

(52) U.S. Cl. CPC H01L 27/1244

(57) ABSTRACT

An array substrate, a display panel, and a display device are provided. The array substrate includes a pixel electrode, a data line, and a conductive unit. The data line is spaced apart from the pixel electrode. The conductive unit includes an accommodating member and multiple conductive particles, where the accommodating member is located between the data line and the pixel electrode, and the accommodating member defines an accommodating cavity. The multiple conductive particles, part of the pixel electrode, and part of the data line are accommodated in the accommodating cavity. The multiple conductive particles are moveable under the control of a control electric-field. The conductive unit is operable in a first state or a second state.

### CROSS-REFERENCE TO RELATED APPLICATIONS

This application claims priority under 35 U.S.C. § 119 (a) to Chinese Patent Application No. 202310981834.4, filed Aug. 7, 2023, the entire disclosure of which is incorporated herein by reference.

### TECHNICAL FIELD

The application relates to the field of display technology, in particular, to an array substrate, a display panel, and a display device.

### BACKGROUND

Currently, transmission of display signals in display panels mainly relies on thin-film transistor (TFT) devices. The transmission principle of TFT devices relates to a structural design based on the characteristics of semiconductors.

However, parasitic capacitance tends to occur between the gate of the display panel and the source and the drain of the TFT, causing image sticking and poor display quality of the display panel, which is not conducive to improving the performance of the display panel.

### SUMMARY

In a first aspect, the disclosure provides an array substrate. The array substrate includes a pixel electrode(s), a data line, and a conductive unit. The data line is spaced apart from the pixel electrode. One end of the conductive unit is connected to the pixel electrode, and the other end of the conductive unit is connected to the data line; the conductive unit includes an accommodating member and multiple conductive particles, where the accommodating member is located between the data line and the pixel electrode, and the accommodating member defines an accommodating cavity; the multiple conductive particles, part of the pixel electrode, and part of the data line are accommodated in the accommodating cavity; and the multiple conductive particles are moveable under the control of a control electric-field. The conductive unit is operable in a first state or a second state. When the conductive unit is in the first state, the data line and the pixel electrode are conducted by the multiple conductive particles under the control of the control electric-field. When the conductive unit is in the second state, an electrical connection between the data line and the pixel electrode is disconnected by the multiple conductive particles under the control of the control electric-field.

In a second aspect, the disclosure further provides a display panel, and the display panel includes the array substrate.

In a third aspect, the disclosure further provides a display device. The display device includes a processor and the display panel. The processor is configured to control the control electric-field to conduct or disconnect the electrical connection between the data line and the pixel electrode. The display panel includes the pixel electrode, the data line, and the conductive unit.

### BRIEF DESCRIPTION OF THE DRAWINGS

In order to describe technical solutions in the related art or embodiments of the disclosure more clearly, the following will give a brief introduction to the accompanying drawings required for describing the related art or embodiments. Apparently, the accompanying drawings hereinafter described are merely some embodiments of the disclosure. Based on these drawings, those of ordinary skill in the art can also obtain other drawings without creative effort.

FIG. 1 is a schematic structural view of a display device and a display panel provided in an embodiment of the disclosure.

FIG. 2 is a partial cross-sectional schematic structural view of the display panel provided in FIG. 1, taken along line A-A.

FIG. 3 is a partially enlarged schematic structural view of the display panel at portion a provided in FIG. 2.

FIG. 4 is a partial schematic structural view of a display panel provided in an embodiment of the disclosure.

FIG. 5 is a partially enlarged schematic structural view of the display panel at portion b provided in FIG. 4.

FIG. 6 is a partial cross-sectional schematic structural view of the display panel provided in embodiment 2 of the disclosure, taken along line A-A.

FIG. 7 is a partially enlarged schematic structural view of the display panel at portion c provided in FIG. 6.

FIG. 8 is a partial schematic structural view of the display panel provided in embodiment 2 of the disclosure.

FIG. 9 is a partially enlarged schematic structural view of the display panel at portion d provided in FIG. 8.

FIG. 10 is a schematic structural view of a conductive particle provided in an embodiment of the disclosure.

FIG. 11 is a partially enlarged schematic structural view of the display panel at portion a provided in embodiment 3 of the disclosure.

FIG. 12 is a partially enlarged schematic structural view of the display panel at portion c provided in embodiment 3 of the disclosure.

FIG. 13 is a schematic top view of part of a structure of a display panel provided in an embodiment of the disclosure.

Reference signs: 1—display device, 10—display panel, 20—processor, 30—array substrate, 11—pixel electrode, 12—data line, 13—conductive unit, 14—control line, 15—gate transmission line, 16—insulating layer, 17—planarization layer, 18—substrate, 19—pixel unit, 131—accommodating member, 132—conductive particle, 1311—accommodating cavity, 1312—bottom wall, 1313—first side wall, 1314—second side wall, 1315—third side wall, 1316—fourth side wall, 1317—top wall, 1321—charge layer, 1322—conductive layer.

### DETAILED DESCRIPTION

The following will illustrate technical solutions of embodiments of the disclosure clearly and comprehensively with reference to the accompanying drawings of embodiments of the disclosure. Apparently, embodiments described herein are merely some embodiments, rather than all embodiments, of the disclosure. Based on the embodiments of the disclosure, all other embodiments obtained by those of ordinary skill in the art without creative effort shall fall within the protection scope of the disclosure.

The terms “first”, “second”, and the like in the description, claims of the present disclosure, and the above accompanying drawings are used for distinguishing different objects, rather than for describing a specific order. In addition, the terms “include”, “have”, and any variations thereof are intended to cover non-exclusive inclusions. For example, a process, method, system, product, or apparatus that includes a series of steps or units is not limited to the listed steps or units, but optionally further includes steps or units not listed, or optionally further includes other steps or units inherent to the process, method, product, or apparatus.

Reference herein to “embodiment” or “implementation” means that a particular feature, structure, or characteristic described in connection with embodiments or implementations can be included in at least one embodiment of the present disclosure. The appearances of this phrase in various places in the description are not necessarily all referring to the same embodiment, nor are separate or alternative embodiments mutually exclusive of other embodiments. It is apparently and implicitly understood by those of ordinary skill in the art that the embodiments described herein can be combined with other embodiments.

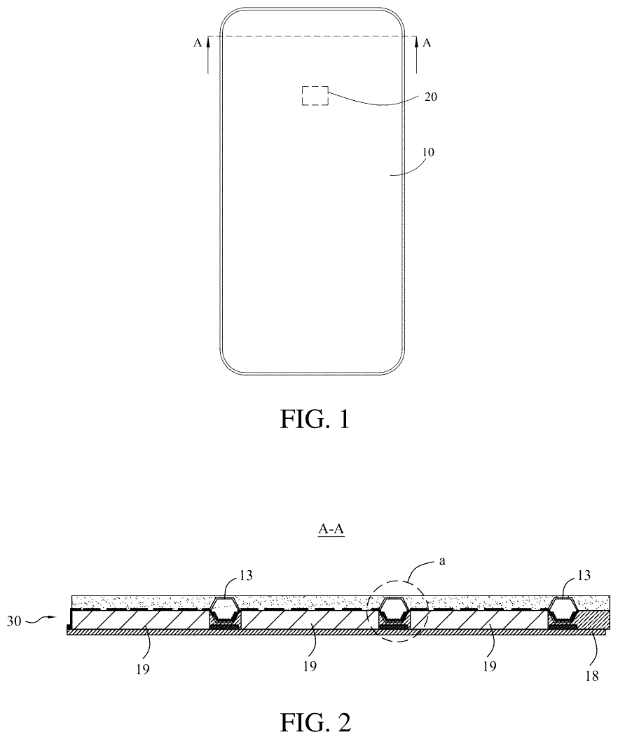

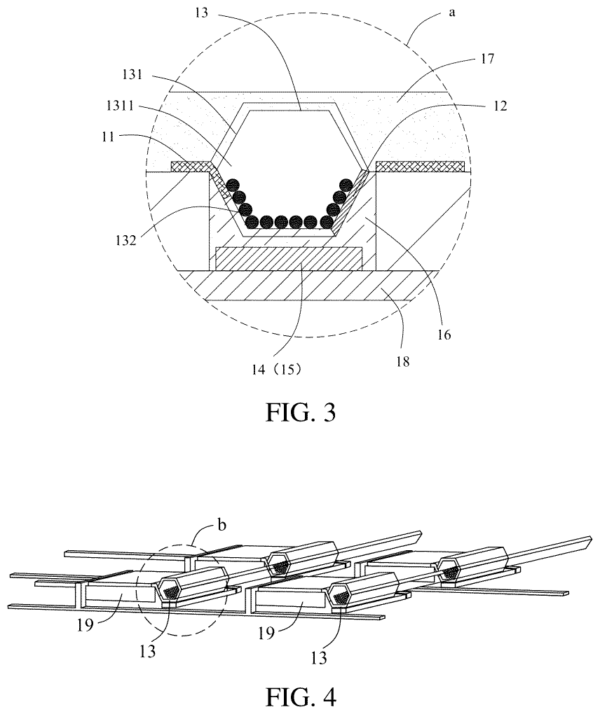

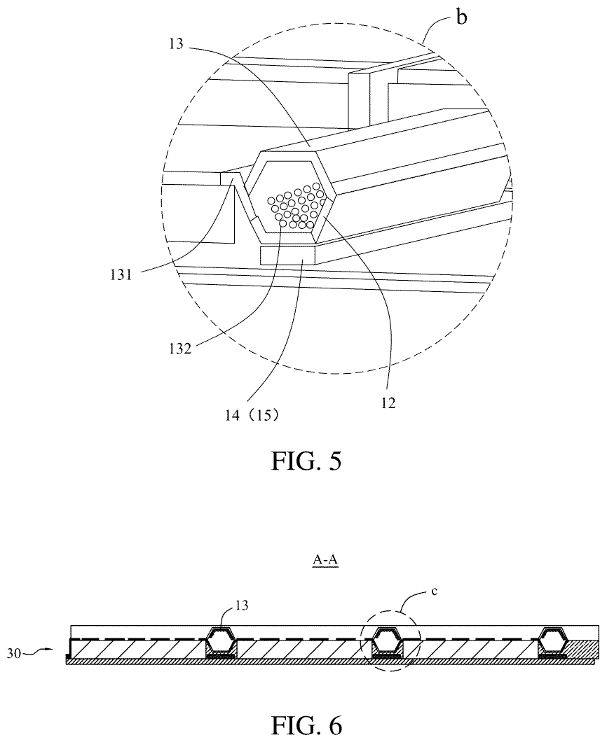

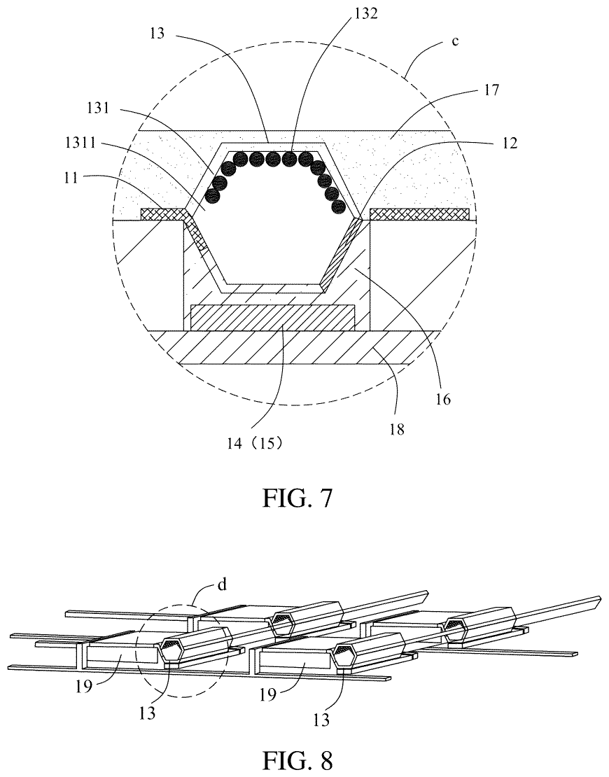

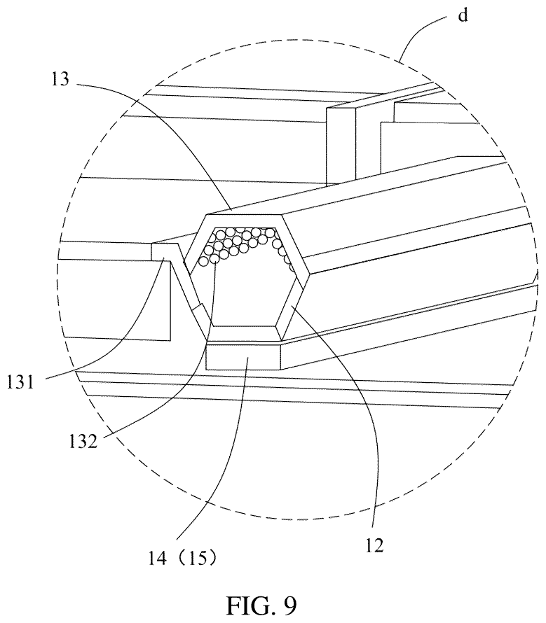

Reference is made to FIG. 1 to FIG. 9. FIG. 1 is a schematic structural view of a display device and a display panel provided in an embodiment of the disclosure. FIG. 2 is a partial cross-sectional schematic structural view of the display panel provided in FIG. 1, taken along line A-A. FIG. 3 is a partially enlarged schematic structural view of the display panel at portion a provided in FIG. 2. FIG. 4 is a partial schematic structural view of a display panel provided in an embodiment of the disclosure. FIG. 5 is a partially enlarged schematic structural view of the display panel at portion b provided in FIG. 4. FIG. 6 is a partial cross-sectional schematic structural view of the display panel provided in embodiment 2 of the disclosure, taken along line A-A. FIG. 7 is a partially enlarged schematic structural view of the display panel at portion c provided in FIG. 6. FIG. 8 is a partial schematic structural view of the display panel provided in embodiment 2 of the disclosure. FIG. 9 is a partially enlarged schematic structural view of the display panel at portion d provided in FIG. 8. The disclosure provides an array substrate 30, and the array substrate 30 includes a pixel electrode(s) 11, a data line 12, and a conductive unit 13. The data line 12 is spaced apart from the pixel electrode 11. One end of the conductive unit 13 is connected to the pixel electrode 11, and the other end of the conductive unit 13 is connected to the data line 12. The conductive unit 13 includes an accommodating member 131 and multiple conductive particles 132, where the accommodating member 131 is located between the data line 12 and the pixel electrode 11, and the accommodating member 131 defines an accommodating cavity 1311. The multiple conductive particles 132, part of the pixel electrode 11, and part of the data line 12 are accommodated in the accommodating cavity 1311. The multiple conductive particles 132 are moveable under the control of a control electric-field. The conductive unit 13 is operable in a first state or a second state. When the conductive unit 13 is in the first state, the data line 12 and the pixel electrode 11 are conducted by the multiple conductive particles 132 under the control of the control electric-field. When the conductive unit 13 is in the second state, an electrical connection between the data line 12 and the pixel electrode 11 is disconnected by the multiple conductive particles 132 under the control of the control electric-field.

Optionally, the array substrate 30 may be applied to the display panel 10, and is configured to transmit and control electrical signals.

Optionally, the display panel 10 may be of various types, including but not limited to a liquid crystal display (LCD) panel, an organic light-emitting diode (OLED) display panel, a twisted nematic (TN) panel, a vertical alignment (VA) panel, an in-plane switching (IPS) panel, or other types of display panels. It may be understood that, the type of the display panel 10 should not constitute as a limitation to the display panel 10 provided in the present embodiment.

Optionally, the material of the pixel electrode 11 may include but is not limited to indium tin oxide (ITO) or other conductive materials. The pixel electrode 11 may be configured to control the operation of a pixel unit 19 of the display panel 10.

Optionally, the number of the pixel electrode 11 may be but is not limited to two, three, four, five, or other numbers. It may be understood that the number of the pixel electrode 11 should not constitute as a limitation to the array substrate 30 provided in the present embodiment.

Optionally, the data line 12 are spaced apart from the pixel electrode 11, and the data line 12 is configured to transmit data signals to the pixel electrode 11. Optionally, in a conventional display panel 10, the data line 12 is usually connected to the pixel electrode 11 through a thin-film transistor (TFT) device, and conducts signal transmission by the TFT device.

In the present embodiment, the conductive unit 13, instead of a conventional TFT device, is disposed between the data line 12 and the pixel electrode 11. Specifically, the conductive unit 13 includes multiple conductive particles 132. The data line 12 and the pixel electrode 11 are conducted by the multiple conductive particles 132 under the control of the control electric-field, and the electrical connection between the data line 12 and the pixel electrode 11 can be realized. Moreover, the electrical connection between the data line 12 and the pixel electrode 11 can be disconnected by the multiple conductive particles 132 under the control of the control electric-field. In this way, the conductive unit 13 can replace the TFT device to control the conduction and disconnection between the data line 12 and the pixel electrode 11.

Optionally, the conductive unit 13 includes the accommodating member 131 and the multiple conductive particles 132. The accommodating member 131 further defines the accommodating cavity 1311, where the multiple conductive particles 132 are accommodated in the accommodating cavity 1311.

Optionally, the accommodating member 131 may be a separate component set in the display panel 10, or the accommodating member 131 may be defined by an insulating layer 16 and a planarization layer 17 of the display panel 10 together. It may be understood that the configuration of the accommodating member 131 should not constitute as a limitation to the display panel 10 provided in the present embodiment.

Optionally, the accommodating cavity 1311 may be an enclosed space or a cavity communicating with the external environment. The cross-sectional shape of the accommodating cavity 1311 may be, but is not limited to, a hexagonal shape, a near-hexagonal shape, a spherical shape, other polygons, or other irregular shapes. It may be understood that the cross-sectional shape of the accommodating cavity 1311 should not constitute as a limitation to the display panel 10 provided by in the present embodiment.

Optionally, the number of the conductive particle 132 may be two, three, four, five, six, or other numbers. It may be understood that the number of the conductive particle 132 should not constitute as a limitation to the display panel 10 provided by in the present embodiment.

Optionally, the accommodating member 131 is located between the data line 12 and the pixel electrode 11. In other words, the data line 12 and the pixel electrode 11 are disposed at two opposite sides of the accommodating member 131.

Optionally, the multiple conductive particles 132, part of the pixel electrode 11, and part of the data line 12 are accommodated in the accommodating cavity 1311. Specifically, part of the pixel electrode 11 may be attached to the pixel unit 19 of the display panel 10, and the remaining part of the pixel electrode 11 may extend into the accommodating cavity 1311. At least part of the data line 12 is accommodated in the accommodating cavity 1311, and the multiple conductive particles 132 are located between the pixel electrode 11 and the data line 12.

Optionally, the conductive unit 13 is operable in the first state and the second state. Specifically, when the conductive unit 13 is in the first state, the display panel 10 needs to transmit data signals to the pixel electrode 11 through the data line 12. In this state, the multiple conductive particles 132 move to a position adjacent to the data line 12 and the pixel electrode 11 under the control of the control electric-field. When the conductive unit 13 is in the second state, the display panel 10 needs to interrupt the transmission of data signals from the data line 12 to the pixel electrode 11. In this state, the multiple conductive particles 132 move to a position away from the data line 12 and the pixel electrode 11 under the control of the control electric-field, and the electrical connection between the data line 12 and the pixel electrode 11 is disconnected. That is, a transmission path of data signals is cut off, thereby cutting off the signals.

It may be noted that, the display panel 10 may include multiple conductive units 13, and each of the multiple conductive units 13 in the display panel 10 may be operable in the first state or the second state. In other words, different conductive units 13 may be operable in different states at the same time. By controlling the switching of the multiple conductive units 13 between the first state and the second state, the display panel 10 can control the pixel electrode 11 and the pixel unit 19 in order to control the image display of the display panel 10.

Optionally, the control electric-field controls the movement of the multiple conductive particle 132 through forces including, but not limited to, magnetic field force, electric field force, or other forces.

In conclusion, the embodiment provides the array substrate 30, including the pixel electrode 11, the data line 12, and the conductive unit 13. The conductive unit 13 includes the accommodating member 131 and the multiple conductive particles 132, where the accommodating member 131 is located between the data line 12 and the pixel electrode 11. The multiple conductive particles 132, part of the pixel electrode 11, and part of the data line 12 are accommodated in the accommodating cavity 1311. The multiple conductive particles 132 are moveable under the control of the control electric-field. The conductive unit 13 is operable in the first state or the second state. When the conductive unit 13 is in the first state, the data line 12 and the pixel electrode 11 are conducted by the multiple conductive particles 132 under the control of the control electric-field. When the conductive unit 13 is in the second state, the electrical connection between the data line 12 and the pixel electrode 11 is disconnected by the multiple conductive particles 132 under the control of the control electric-field. The display panel 10 can control the conduction and disconnection between the data line 12 and the pixel electrode 11 by controlling the movement of the multiple conductive particles 132 in the conductive unit 13. In this way, a novel design for signal transmission is realized. Compared to a traditional structure of the TFT, by providing the conductive unit 13, parasitic capacitance generated between the gate of the display panel 10 and the source and the drain of the TFT can be avoided, thereby avoiding situations such as image sticking and abnormal images and ensuring excellent display quality of the display panel 10.

Reference is again made to FIG. 3, FIG. 5, FIG. 7, and FIG. 9. The array substrate 30 further includes a control line 14, where the control line 14 is disposed at one side of the accommodating member 131, and the control line 14 is configured to load the control electric-field. When the conductive unit 13 is in the first state, the control line 14 loads a first control signal to generate the control electric-field, where the multiple conductive particles 132 are located at a first position adjacent to the control line 14, and the data line 12 and the pixel electrode 11 are conducted by the multiple conductive particles 132. When the conductive unit 13 is in the second state, the control line 14 loads a second control signal to generate the control electric-field, where the multiple conductive particles 132 are located at a second position facing away from the control line 14, and the multiple conductive particles 132 are spaced apart from and insulated from the data line 12 and the pixel electrode 11.

Optionally, in an embodiment of the disclosure, the pixel electrode 11 and the data line 12 are disposed at intervals at two sides of the accommodating cavity 1311. The control line 14 is disposed at one side of the accommodating member 131. The arrangement direction of the control line 14 and the accommodating member 131 may be perpendicular or substantially perpendicular to the arrangement direction of the pixel electrode 11 and the data line 12.

Optionally, in an embodiment of the disclosure, the pixel electrode 11 and the data line 12 are disposed at intervals at two sides of the accommodating cavity 1311. The control line 14 is disposed at one side of the accommodating member 131. The arrangement direction of the control line 14 and the accommodating member 131 may be along or substantially along the arrangement direction of the pixel electrode 11 and the data line 12.

Optionally, the number of control line 14 may be, but is not limited to, one, two, three, four, or any other numbers. It may be understood that the number of control line 14 should not constitute as a limitation to the display panel 10 provided in the present embodiment.

Optionally, the multiple conductive particles 132 may be charged, and the control line 14 may load signals of the same or opposite polarity as the charges of the multiple conductive particles 132. The movement of the multiple conductive particles 132 is controlled under the principle of like charges repelling and opposite charges attracting.

Optionally, in an embodiment of the disclosure, an example where a single control line 14 is disposed at one side of a single conductive unit 13 is used for illustration. The arrangement direction of the control line 14 and the accommodating member 131 is perpendicular or substantially perpendicular to the arrangement direction of the pixel electrode 11 and the data line 12. In this way, when the control line 14 loads the control electric-field, the control line 14 can control the movement of the multiple conductive particles 132 in a direction perpendicular or substantially perpendicular to the arrangement direction of the pixel electrode 11 and the data line 12. The control line 14 may be disposed at one side of the accommodating member 131 adjacent to the pixel electrode 11 and the data line 12. Therefore, when the conductive unit 13 is in the first state, the control line 14 loads the first control signal, and the control electric-field generated by the first control signal attracts the multiple conductive particles 132, resulting in that the multiple conductive particles 132 move to the first position adjacent to the control line 14 and the data line 12 and the pixel electrode 11 are conducted by the multiple conductive particles 132. When the conductive unit 13 is in the second state, the control line 14 loads the second control signal, and the control electric-field generated by the second control signal repels the multiple conductive particles 132, resulting in that the multiple conductive particles 132 move to the second position facing away from the control line 14 and the multiple conductive particles 132 are spaced apart from and insulated from the data line 12 and the pixel electrode 11. In this way, the electrical connection between the data line 12 and the pixel electrode 11 is disconnected, and the signals are cut off. That is, a novel design for signal transmission is realized, and thus avoiding issues such as image sticking and abnormal images of the display panel 10, ensuring the optical quality and product yield of the display panel 10.

It may be understood that, in other embodiments of the disclosure, the control line 14 may be disposed at one side of the accommodating member 131 facing away from the pixel electrode 11 and the data line 12. Specifically, when the conductive unit 13 is in the first state, the control line 14 loads the first control signal, and the control electric-field generated by the first control signal repels the multiple conductive particles 132. When the conductive unit 13 is in the second state, the control line 14 loads the second control signal, and the control electric-field generated by the second control signal attracts the multiple conductive particles 132. In this way, the conduction and disconnection of the electrical connection between the data line 12 and the pixel electrode 11 can be separately achieved.

It may be understood that, in other embodiments of the disclosure, the arrangement direction of the control line 14 and the accommodating member 131 may be along or substantially along the arrangement direction of the pixel electrode 11 and the data line 12. The number of control line 14 may be multiple, and multiple control lines 14 may be disposed at two opposite sides of the accommodating member 131. By attracting or repelling the multiple conductive particles 132 through the control electric-field, the multiple conductive particles 132 may be moved to positions adjacent to or facing away from the data line 12 and the pixel electrode 11, thereby achieving the transmission of signals for the conduction or disconnection between the data line 12 and the pixel electrode 11.

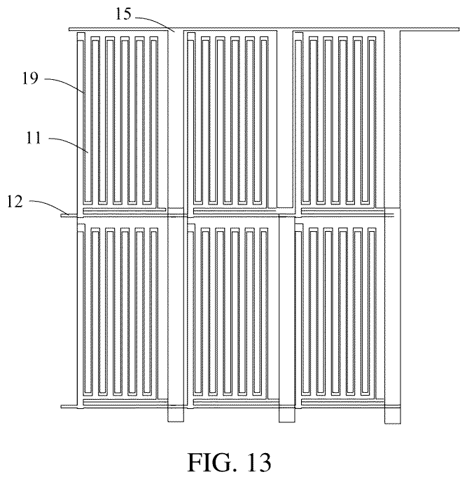

Reference is again made to FIG. 3, FIG. 5, FIG. 7, FIG. 9, and FIG. 13. FIG. 13 is a schematic top view of part of a structure of a display panel provided in an embodiment of the disclosure. The array substrate 30 further includes a gate transmission line 15, which is served as the control line 14.

Optionally, in an embodiment of the disclosure, an example where the gate transmission line 15 of the array substrate 30 is served as the control line 14 is used for illustration.

Specifically, the gate transmission line 15 may be disposed at one side of the conductive unit 13. The gate transmission line 15 may transmit gate signals in the array substrate 30, and may be served as the control line 14 to generate the control electric-field to control the movement of the multiple conductive particles 132. In the present embodiment, by reusing the gate transmission line 15, there is no need to additionally arrange the control line 14 in the display panel 10, thereby avoiding an increase in the manufacturing process and cost of the array substrate 30, and making the array substrate 30 more widely applicable.

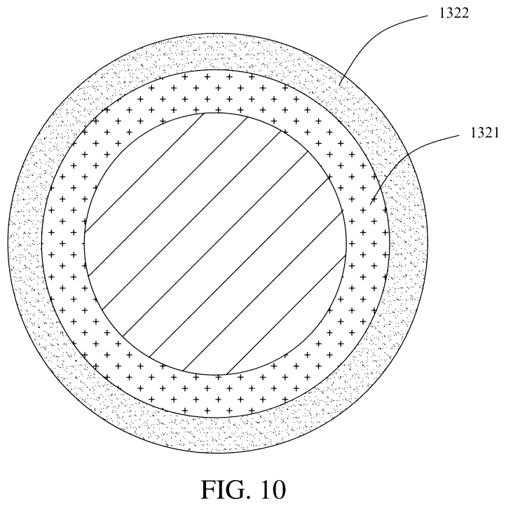

Reference is made to FIG. 3, FIG. 7, and FIG. 10. FIG. 10 is a schematic structural view of a conductive particle provided in an embodiment of the disclosure. The conductive particle 132 includes a charge layer 1321 and a conductive layer 1322, the charge layer 1321 carries a charge of a first polarity, and the conductive layer 1322 envelops an outer surface of the charge layer 1321. When the gate transmission line 15 loads a second polarity voltage signal as the first control signal, the multiple conductive particles 132 are located at a first position adjacent to the gate transmission line 15. When the gate transmission line 15 loads a first polarity voltage signal as the second control signal, the multiple conductive particles 132 are located at a second position facing away from the gate transmission line 15.

Optionally, the conductive particle 132 includes the charge layer 1321 and the conductive layer 1322. The conductive layer 1322 envelops the outer surface of the charge layer 1321. The conductive particle 132 may be composed of the charge layer 1321 and the conductive layer 1322, or the conductive particle 132 may be composed of the charge layer 1321, the conductive layer 1322, and a base material or a hollow cavity at one side of the charge layer 1321 facing away from the conductive layer 1322, which will not be limited in the disclosure.

Optionally, the charge layer 1321 carries a charge of the first polarity, and the first polarity may be but is not limited to, positive (“+”) or negative (“−”).

Optionally, the second polarity may be but is not limited to, negative (“−”) or positive (“+”), and the second polarity may be opposite to the first polarity.

Optionally, the material of the conductive layer 1322 may be but is not limited to, metal, non-metal, composite material, or other conductive materials. For example, the material of the conductive layer 1322 may be gold (Au). In the manufacturing process of the display panel 10, the coating process of gold (Au) is relatively mature and can provide good conductivity for the conductive layer 1322. It may be understood that, the material of the conductive layer 1322 may be copper, carbon black, or other materials with good conductivity. The material of the conductive layer 1322 should not constitute as a limitation to the display panel 10 provided in the present embodiment.

It may be noted that, in the present embodiment, the gate transmission line 15 controls the multiple conductive particles 132 under the principle of like charges repelling and opposite charges attracting. In other words, the force exerted by the gate transmission line 15 on the multiple conductive particles 132 includes vertical magnetic force, ensuring that the charge layer 1321 is not shielded by the conductive layer 1322.

Further optionally, the conductive layer 1322 may have openings, or may be a metal mesh or a carbon fiber mesh, thereby further ensuring the effective force between the gate transmission line 15 and the charge layer 1321.

In the present embodiment, the first polarity of the charge may be positive (“+”) or negative (“−”). When the polarity of the charge is positive, the gate transmission line 15 can load a voltage signal with a negative polarity as the first control signal. In this way, the multiple conductive particles 132 may be attracted to a position adjacent to the gate transmission line 15 under the effect of the first control signal. The gate transmission line 15 can load a voltage signal with a positive polarity as the second control signal. In this way, the multiple conductive particles 132 may be repelled to a position facing away from the gate transmission line 15 under the effect of the second control signal. Thus, the conduction and disconnection between the pixel electrode 11 and the data line 12 can be respectively realized. The arrangement of the charge layer 1321 ensures that the gate transmission line 15 can precisely control the movement of the multiple conductive particles 132. The conductive layer 1322 can be served as a bridge channel for signal transmission, ensuring a rapid signal transmission in the case where the pixel electrode 11 and the data line 12 are conducted.

Reference is again made to FIG. 3 and FIG. 7. When the gate transmission line 15 loads the first control signal, at least part of the multiple conductive particles 132 abut against the data line 12, at least the remaining part of the multiple conductive particles 132 abut against the pixel electrode 11, and a data signal is transmitted to the pixel electrode 11. When the gate transmission line 15 loads the second control signal, the multiple conductive particles 132 are spaced apart from at least one of the data line 12 and the pixel electrode 11, and the electrical connection between the data line 12 and the pixel electrode 11 is disconnected.

Optionally, when the gate transmission line 15 loads the first control signal, at least part of the multiple conductive particles 132 abut against the data line 12, and at least the remaining part of the multiple conductive particles 132 abut against the pixel electrode 11. The multiple conductive particles 132 may be sequentially abut against one another, allowing that the data signal output by the data line 12 can be transmitted to the pixel electrode 11 through the multiple conductive particles 132.

Optionally, when the gate transmission line 15 loads the second control signal, the multiple conductive particles 132 are spaced apart from one of the data line 12 and the pixel electrode 11, or the multiple conductive particles 132 are spaced apart from both the data line 12 and the pixel electrode 11, thereby disconnecting the electrical connection between the data line 12 and the pixel electrode 11, and interrupting the transmission of data signals.

Optionally, the conductive unit 13 may be disposed between two adjacent pixel units 19. Optionally, the multiple conductive particles 132 may be made of opaque materials, allowing the multiple conductive particles 132 to partially or completely replace the black matrix (BM) structure in the conventional display panel 10 between two adjacent pixel units 19. In this way, the use of related materials in the manufacturing process of the display panel 10 can be reduced, and masking processes of the display panel 10 can be reduced, thereby effectively controlling the production cost and machining time of the display panel 10.

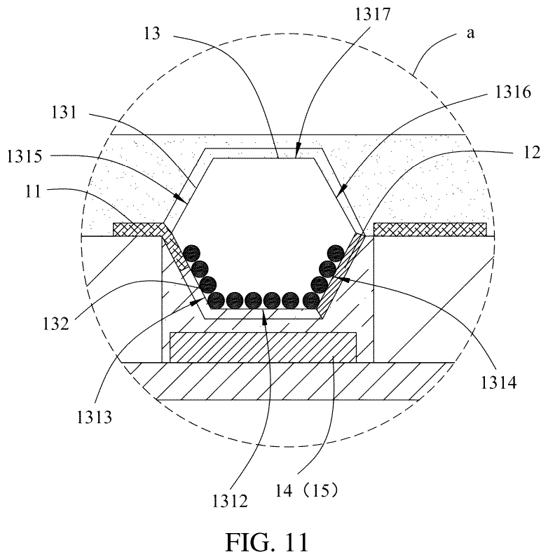

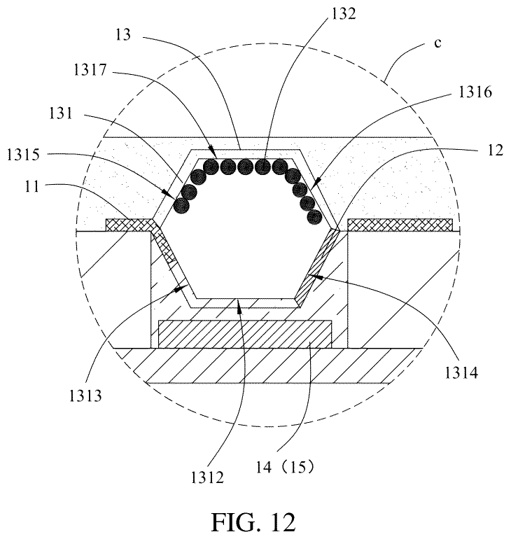

Reference is made to FIG. 11 and FIG. 12. FIG. 11 is a partially enlarged schematic structural view of the display panel at portion a provided in embodiment 3 of the disclosure. FIG. 12 is a partially enlarged schematic structural view of the display panel at portion c provided in embodiment 3 of the disclosure. The accommodating member 131 has a bottom wall 1312, a first side wall 1313, a second side wall 1314, a third side wall 1315, a fourth side wall 1316, and a top wall 1317, which define the accommodating cavity 1311. The first side wall 1313 is connected to the bottom wall 1312 in a bent manner, the second side wall 1314 is connected to the bottom wall 1312 in a bent manner and is opposite to the first side wall 1313, the third side wall 1315 is connected to the first side wall 1313 in a bent manner and faces away from the bottom wall 1312, the fourth side wall 1316 is connected to the second side wall 1314 in a bent manner and is opposite to the third side wall 1315, and the top wall 1317 is connected to the third side wall 1315 and the fourth side wall 1316 in a bent manner and is opposite to the bottom wall 1312. Part of the pixel electrode 11 is disposed at a part of the first side wall 1313 adjacent to the third side wall 1315, and the data line 12 is disposed at the second side wall 1314. When the conductive unit 13 is in the first state, the multiple conductive particles 132 abut against one another and are electrically connected to one another, part of the multiple conductive particles 132 cover and are electrically connected to the pixel electrode 11, part of the multiple conductive particles 132 cover one end of the first side wall 1313 facing away from the third side wall 1315, part of the multiple conductive particles 132 cover the bottom wall 1312, and part of the multiple conductive particles 132 cover and are electrically connected to the data line 12.

Optionally, in an embodiment of the disclosure, an example where the cross-sectional shape of the accommodating member 131 is a hexagonal shape or a near-hexagonal shape is used for illustration.

Specifically, the accommodating member 131 has the bottom wall 1312, the first side wall 1313, the second side wall 1314, the third side wall 1315, the fourth side wall 1316, and the top wall 1317, which define the accommodating cavity 1311. The first side wall 1313, the bottom wall 1312, the second side wall 1314, the fourth side wall 1316, the top wall 1317, and the third side wall 1315 are sequentially connected in a bent manner. The first side wall 1313, the bottom wall 1312, the second side wall 1314, the fourth side wall 1316, the top wall 1317, and the third side wall 1315 together can enclose a hexagonal shape or a near-hexagonal shape.

Optionally, the second side wall 1314 is opposite to the first side wall 1313, that is, the second side wall 1314 and the first side wall 1313 can be symmetrically arranged or nearly symmetrically arranged relative to the central axis of the accommodating member 131.

Optionally, part of the pixel electrode 11 is disposed at a part of the first side wall 1313 adjacent to the third side wall 1315, and the remaining part of the pixel electrode 11 is disposed at the pixel unit 19 of the display panel 10.

Optionally, the data line 12 is disposed at the second side wall 1314 and is opposite to part of the pixel electrode 11.

Optionally, when the conductive unit 13 is in the first state, the multiple conductive particles 132 abut against one another and are electrically connected to one another. Part of the pixel electrode 11 is disposed at the part of the first side wall 1313 adjacent to the third side wall 1315 and the data line 12 is disposed at the second side wall 1314. In this way, when the multiple conductive particles 132 are disposed adjacent to the bottom wall 1312, the first side wall 1313, and the second side wall 1314, part of the multiple conductive particles 132 may cover a surface of the pixel electrode 11 and may be electrically connected to the pixel electrode 11, and part of the multiple conductive particles 132 may cover a surface of the data line 12 and may be electrically connected to the data line 12. Therefore, when the conductive unit 13 is in the first state, the multiple conductive particles 132 may quickly conduct the pixel electrode 11 and the data line 12, allowing the display panel 10 to respond quickly and switch display images.

Reference is again made to FIG. 11 and FIG. 12. When the conductive unit 13 is in the second state, part of the multiple conductive particles 132 cover the third side wall 1315 and are spaced apart from and insulated from the pixel electrode 11; part of the multiple conductive particles 132 cover the fourth side wall 1316 and are spaced apart from and insulated from the data line 12; and part of the multiple conductive particles 132 cover the top wall 1317.

Optionally, when the conductive unit 13 is in the second state, the multiple conductive particles 132 may be located at positions of the top wall 1317, the third side wall 1315, and the fourth side wall 1316 under the control electric-field. The pixel electrode 11 is disposed at the first side wall 1313, and the data line 12 is disposed at the second side wall 1314. In this way, when the conductive unit 13 is in the second state, the multiple conductive particles 132 may be spaced apart from and insulated from the pixel electrode 11, and the multiple conductive particles 132 may be spaced apart from and insulated from the data line 12. Therefore, a quick cut-off of the transmission of data signals can be realized, allowing the display panel 10 to respond quickly.

Optionally, when the conductive unit 13 is in the second state, the multiple conductive particles 132 may be, but are not limited to, abutted against one another, or not abutted against one another. Part of the multiple conductive particles 132 may cover the top wall 1317, or all of the multiple conductive particles 132 may cover the top wall 1317, which will not be limited in the disclosure.

Reference is again made to FIG. 3 and FIG. 7. The array substrate 30 further includes the insulating layer 16, where part of the insulating layer 16 is disposed between the control line 14 and the pixel electrode 11, and is configured to insulate the control line 14 from the pixel electrode 11. Part of the insulating layer 16 is disposed between the control line 14 and the conductive unit 13, and is configured to insulate the control line 14 from the conductive unit 13.

Optionally, the array substrate 30 may further include a substrate 18. The control line 14 is disposed at the substrate 18. The insulating layer 16 may cover a surface of the control line 14 facing away from the substrate 18, allowing the control line 14 to be insulated from the pixel electrode 11 and the conductive unit 13, thereby protecting the control line 14, the pixel electrode 11, and the conductive unit 13. In this way, the display panel 10 can be prevented from burnout due to the short-circuit of the array substrate 30, thereby ensuring the safe operation of the display panel 10.

Optionally, the material of the insulating layer 16 may be, but is not limited to, silicon oxide (SiOx), silicon nitride (SiNx), polyvinylpyrrolidone (PVP), polyimide (P1), or other materials. It may be understood that the material of the insulating layer 16 should not constitute as a limitation to the array substrate 30 provided in the present embodiment.

Reference is again made to FIG. 3 and FIG. 7. The array substrate 30 further includes the planarization layer 17, where the planarization layer 17 is disposed at a surface of the pixel electrode 11 facing away from the insulating layer 16 and a surface of the conductive unit 13 facing away from the insulating layer 16, and the planarization layer 17 and the insulating layer 16 cooperatively define the accommodating cavity 1311.

Optionally, the planarization layer 17 (PFA) may cover the surface of the pixel electrode 11 facing away from the insulating layer 16 and the surface of the conductive unit 13 facing away from the insulating layer 16. The planarization layer 17 and the insulating layer 16 cooperatively define the accommodating cavity 1311. In this way, the accommodating cavity 1311 can be obtained by adding an etching process or other process to the planar layer 17 and the insulating layer 16 in the normal manufacturing process of the array substrate 30, thereby simplifying the preparation process of the conductive unit 13.

Optionally, the display panel 10 may further include the pixel units 19. The pixel unit 19 is disposed at the substrate 18, and the pixel electrode 11 is disposed at one side of the pixel unit 19 facing away from the substrate 18. There are multiple pixel units 19, and the multiple pixel units 19 are spaced apart from one another. The conductive unit 13 is disposed at a gap between the two adjacent pixel units 19. The planarization layer 17 can cover the surfaces of the pixel unit 19, the pixel electrode 11, and the conductive unit 13, so as to achieve planarization between the pixel unit 19, the pixel electrode 11, and the conductive unit 13, making the display panel 10 possess a uniform and excellent display effect.

Optionally, in an embodiment of the disclosure, the preparation process of the conductive unit 13 may include the following steps. At step one, the pixel unit 19 is prepared through deposition or other processes. At step two, the control line 14 is prepared. At step three, the insulating layer 16 is prepared through evaporation or other processes. At step four, the insulating layer 16 is etched, and the accommodating cavity 1311 is defined. At step five, the pixel electrode 11 is prepared through evaporation or other processes. At step six, multiple microspheres are placed in the accommodating cavity 1311, and a transparent mold is inserted into the accommodating cavity 1311. At step seven, the planarization layer 17 is prepared through evaporation or other processes. It may be understood that, in other embodiments of the disclosure, the conductive unit 13 may be obtained through other processes. The preparation process and preparation flow of the conductive unit 13 should not constitute as a limitation to the display panel 10 provided in the present embodiment.

Reference is again made to FIG. 1 and FIG. 2. The disclosure further provides a display panel 10, which includes the array substrate 30.

Optionally, in an embodiment of the disclosure, the display panel 10 may be a LCD panel, and the pixel unit 19 may include a color-resist layer. In the present embodiment, the color-filter on array (COA) technology, which combines a color filter (CF) substrate of the display panel 10 and the array substrate 30, may be adopted to prepare the display panel 10. In this way, the manufacturing process of the display panel 10 can be significantly simplified, an inaccurate alignment between the color-resist layer and the array substrate 30 of the display panel 10 can be avoided, and a problem of low aperture ratio of a traditional color-resist layer can be improved.

Further optionally, in another embodiment of the disclosure, the display panel 10 may be an OLED display panel, and the pixel unit 19 may include an organic light-emitting layer, an anode, and a cathode. The organic light-emitting layer may be sandwiched between the cathode and the anode, and the organic light-emitting layer emits light under the combined action of the cathode and the anode.

Reference is again made to FIG. 1, FIG. 2, and FIG. 3. The disclosure further provides a display device 1, which includes a processor 20 and the display panel 10. The processor 20 is configured to control the control electric-field to conduct or disconnect the electrical connection between the data line 12 and the pixel electrode 11.

Optionally, the display device 1 may be, but is not limited to, a LCD device, a mini-light emitting diode (Mini-LED) display device, a micro-light emitting diode (Micro-LED) display device, or an OLED display device. It may be understood that, the display device 1 may be of other functional types, and the functional type of the display device 1 should not constitute as a limitation to the display device 1 provided in the present embodiment.

Optionally, the processor 20 may be disposed in the display device 1 to control the control electric-field, so as to conduct or disconnect the electrical connection between the data line 12 and the pixel electrode 11. Specifically, the display panel 10 includes the pixel electrode 11, the data line 12, and the conductive unit 13. The conductive unit 13 includes the accommodating member 131 and the multiple conductive particles 132, where the accommodating member 131 is located between the data line 12 and the pixel electrode 11. The multiple conductive particles 132, part of the pixel electrode 11, and part of the data line 12 are accommodated in the accommodating cavity 1311. The multiple conductive particles 132 are moveable under the control of the control electric-field. The conductive unit 13 is operable in the first state or the second state. When the conductive unit 13 is in the first state, the data line 12 and the pixel electrode 11 are conducted by the multiple conductive particles 132 under the control of the control electric-field. When the conductive unit 13 is in the second state, the electrical connection between the data line 12 and the pixel electrode 11 is disconnected by the multiple conductive particles 132 under the control of the control electric-field. The display panel 10 can control the conduction and disconnection between the data line 12 and the pixel electrode 11 by controlling the movement of the multiple conductive particles 132 in the conductive unit 13. In this way, a novel design for signal transmission is realized. Compared to a traditional structure of the TFT, by providing the conductive unit 13, parasitic capacitance generated between the gate of the display panel 10 and the source and the drain of the TFT can be avoided, and the coupling effect between the data line 12 and the pixel electrode 11 can be reduced, thereby avoiding situations such as image sticking and abnormal images, and ensuring excellent display quality of the display panel 10 and the display device 1.

The terms of “embodiment” and “implementation” mentioned in the present disclosure means that the specific features, structures, or characteristics described with reference to the embodiments may be encompassed in at least one embodiment of the present disclosure. The phrase at various locations in the specification does not necessarily refer to the same embodiment, or an independent or alternative embodiment exclusive of another embodiment. Those skilled in the art may understand explicitly and implicitly that the embodiments described in the present disclosure may be combined with other embodiments. In addition, it may also be understood that the features, structures or characteristics described in embodiments of the present disclosure may be combined as desired to obtain embodiments without departing from the spirit and scope of the technical solution of the present disclosure if there is no contradiction between the embodiments.

Finally, it may be noted that the above implementations are merely used for illustrating rather than limiting the technical solutions of the present disclosure; and although the present disclosure has been described in detail with reference to the preferred implementations, those skilled in the art may understand that modifications or equivalent substitutions may be made to the technical solutions of the present disclosure without departing from the spirit and scope of the technical solutions of the present disclosure.

What is claimed is:

1. An array substrate, comprising:
a pixel electrode;
a data line, wherein the data line is spaced apart from the pixel electrode; and
a conductive unit, wherein one end of the conductive unit is connected to the pixel electrode, and the other end of the conductive unit is connected to the data line; the conductive unit comprises an accommodating member and a plurality of conductive particles, wherein the accommodating member is located between the data line and the pixel electrode, and the accommodating member defines an accommodating cavity; the plurality of conductive particles, part of the pixel electrode, and part of the data line are accommodated in the accommodating cavity; and the plurality of conductive particles are moveable under control of a control electric-field;
wherein the conductive unit is operable in a first state or a second state; in response to the conductive unit being in the first state, the data line and the pixel electrode are conducted by the plurality of conductive particles under the control of the control electric-field; and in response to the conductive unit being in the second state, an electrical connection between the data line and the pixel electrode is disconnected by the plurality of conductive particles under the control of the control electric-field.

2. The array substrate of claim 1, further comprising:
a control line, wherein the control line is disposed at a side of the accommodating member, and the control line is configured to load the control electric-field;
in response to the conductive unit being in the first state, the control line loads a first control signal to generate the control electric-field, wherein the plurality of conductive particles are located at a first position adjacent to the control line, and the data line and the pixel electrode are conducted by the plurality of conductive particles;
in response to the conductive unit being in the second state, the control line loads a second control signal to generate the control electric-field, wherein the plurality of conductive particles are located at a second position facing away from the control line, and the plurality of conductive particles are spaced apart from and insulated from the data line and the pixel electrode.

3. The array substrate of claim 2, further comprising:
a gate transmission line, wherein the gate transmission line is served as the control line.

4. The array substrate of claim 3, wherein the conductive particle comprises a charge layer and a conductive layer, the charge layer carries a charge of a first polarity, and the conductive layer envelops an outer surface of the charge layer;
in response to the gate transmission line loading a second polarity voltage signal as the first control signal, the plurality of conductive particles are located at a first position adjacent to the gate transmission line; and
in response to the gate transmission line loading a first polarity voltage signal as the second control signal, the plurality of conductive particles are located at a second position facing away from the gate transmission line.

5. The array substrate of claim 3, wherein
in response to the gate transmission line loading the first control signal, at least part of the plurality of conductive particles abut against the data line, at least a remaining part of the plurality of conductive particles abut against the pixel electrode, and a data signal is transmitted to the pixel electrode; and
in response to the gate transmission line loading the second control signal, the plurality of conductive particles are spaced apart from at least one of the data line and the pixel electrode, and the electrical connection between the data line and the pixel electrode is disconnected.

6. The array substrate of claim 1, wherein the accommodating member has a bottom wall, a first side wall, a second side wall, a third side wall, a fourth side wall, and a top wall, which define the accommodating cavity; the first side wall is connected to the bottom wall in a bent manner, the second side wall is connected to the bottom wall in a bent manner and is opposite to the first side wall, the third side wall is connected to the first side wall in a bent manner and faces away from the bottom wall, the fourth side wall is connected to the second side wall in a bent manner and is opposite to the third side wall, and the top wall is connected to the third side wall and the fourth side wall in a bent manner and is opposite to the bottom wall;
part of the pixel electrode is disposed at a part of the first side wall adjacent to the third side wall, and the data line is disposed at the second side wall; and
in response to the conductive unit being in the first state, the plurality of conductive particles abut against one another and are electrically connected to one another, part of the plurality of conductive particles cover and are electrically connected to the pixel electrode, part of the plurality of conductive particles cover one end of the first side wall facing away from the third side wall, part of the plurality of conductive particles cover the bottom wall, and part of the plurality of conductive particles cover and are electrically connected to the data line.

7. The array substrate of claim 6, wherein in response to the conductive unit being in the second state, part of the plurality of conductive particles cover the third side wall and are spaced apart from and insulated from the pixel electrode; part of the plurality of conductive particles cover the fourth side wall and are spaced apart from and insulated from the data line; and part of the plurality of conductive particles cover the top wall.

8. The array substrate of claim 2, further comprising:
an insulating layer, wherein part of the insulating layer is disposed between the control line and the pixel electrode, and is configured to insulate the control line from the pixel electrode; part of the insulating layer is disposed between the control line and the conductive unit, and is configured to insulate the control line from the conductive unit; and
a planarization layer, wherein the planarization layer is disposed at a surface of the pixel electrode facing away from the insulating layer and a surface of the conductive unit facing away from the insulating layer, and the planarization layer and the insulating layer cooperatively define the accommodating cavity.

9. A display panel, comprising an array substrate, wherein the array substrate comprises:
a pixel electrode;
a data line, wherein the data line is spaced apart from the pixel electrode; and
a conductive unit, wherein one end of the conductive unit is connected to the pixel electrode, and the other end of the conductive unit is connected to the data line; the conductive unit comprises an accommodating member and a plurality of conductive particles, wherein the accommodating member is located between the data line and the pixel electrode, and the accommodating member defines an accommodating cavity; the plurality of conductive particles, part of the pixel electrode, and part of the data line are accommodated in the accommodating cavity; and the plurality of conductive particles are moveable under control of a control electric-field;
wherein the conductive unit is operable in a first state or a second state; in response to the conductive unit being in the first state, the data line and the pixel electrode are conducted by the plurality of conductive particles under the control of the control electric-field; and in response to the conductive unit being in the second state, an electrical connection between the data line and the pixel electrode is disconnected by the plurality of conductive particles under the control of the control electric-field.

10. The display panel of claim 9, wherein the array substrate further comprising:
a control line, wherein the control line is disposed at a side of the accommodating member, and the control line is configured to load the control electric-field;
in response to the conductive unit being in the first state, the control line loads a first control signal to generate the control electric-field, wherein the plurality of conductive particles are located at a first position adjacent to the control line, and the data line and the pixel electrode are conducted by the plurality of conductive particles;
in response to the conductive unit being in the second state, the control line loads a second control signal to generate the control electric-field, wherein the plurality of conductive particles are located at a second position facing away from the control line, and the plurality of conductive particles are spaced apart from and insulated from the data line and the pixel electrode.

11. The display panel of claim 10, wherein the array substrate further comprising:
a gate transmission line, wherein the gate transmission line is served as the control line.

12. The display panel of claim 11, wherein the conductive particle comprises a charge layer and a conductive layer, the charge layer carries a charge of a first polarity, and the conductive layer envelops an outer surface of the charge layer;
in response to the gate transmission line loading a second polarity voltage signal as the first control signal, the plurality of conductive particles are located at a first position adjacent to the gate transmission line; and
in response to the gate transmission line loading a first polarity voltage signal as the second control signal, the plurality of conductive particles are located at a second position facing away from the gate transmission line.

13. The display panel of claim 11, wherein
in response to the gate transmission line loading the first control signal, at least part of the plurality of conductive particles abut against the data line, at least a remaining part of the plurality of conductive particles abut against the pixel electrode, and a data signal is transmitted to the pixel electrode; and
in response to the gate transmission line loading the second control signal, the plurality of conductive particles are spaced apart from at least one of the data line and the pixel electrode, and the electrical connection between the data line and the pixel electrode is disconnected.

14. The display panel of claim 9, wherein the accommodating member has a bottom wall, a first side wall, a second side wall, a third side wall, a fourth side wall, and a top wall, which define the accommodating cavity; the first side wall is connected to the bottom wall in a bent manner, the second side wall is connected to the bottom wall in a bent manner and is opposite to the first side wall, the third side wall is connected to the first side wall in a bent manner and faces away from the bottom wall, the fourth side wall is connected to the second side wall in a bent manner and is opposite to the third side wall, and the top wall is connected to the third side wall and the fourth side wall in a bent manner and is opposite to the bottom wall;
part of the pixel electrode is disposed at a part of the first side wall adjacent to the third side wall, and the data line is disposed at the second side wall; and
in response to the conductive unit being in the first state, the plurality of conductive particles abut against one another and are electrically connected to one another, part of the plurality of conductive particles cover and are electrically connected to the pixel electrode, part of the plurality of conductive particles cover one end of the first side wall facing away from the third side wall, part of the plurality of conductive particles cover the bottom wall, and part of the plurality of conductive particles cover and are electrically connected to the data line.

15. The display panel of claim 14, wherein in response to the conductive unit being in the second state, part of the plurality of conductive particles cover the third side wall and are spaced apart from and insulated from the pixel electrode; part of the plurality of conductive particles cover the fourth side wall and are spaced apart from and insulated from the data line; and part of the plurality of conductive particles cover the top wall.

16. The display panel of claim 10, further comprising:
an insulating layer, wherein part of the insulating layer is disposed between the control line and the pixel electrode, and is configured to insulate the control line from the pixel electrode; part of the insulating layer is disposed between the control line and the conductive unit, and is configured to insulate the control line from the conductive unit; and
a planarization layer, wherein the planarization layer is disposed at a surface of the pixel electrode facing away from the insulating layer and a surface of the conductive unit facing away from the insulating layer, and the planarization layer and the insulating layer cooperatively define the accommodating cavity.

17. A display device, comprising a processor and the display panel of claim 9, wherein the processor is configured to control the control electric-field to conduct or disconnect the electrical connection between the data line and the pixel electrode.
